(19) United States
(12) Patent Application Publication
(10) Pub. No.: US 2023/0161929 A1
(43) Pub. Date: May 25, 2023

(54) ESTIMATION METHOD, SIMULATION METHOD, ESTIMATION DEVICE, AND ESTIMATION PROGRAM

(71) Applicant: NIPPON TELEGRAPH AND TELEPHONE CORPORATION, Tokyo (JP)

(72) Inventors: Midori KODAMA, Tokyo (JP); Nobuhiko MATSUURA, Tokyo (JP); Keisuke TSUNODA, Tokyo (JP); Motonori NAKAMURA, Tokyo (JP); Kazuaki OBANA, Tokyo (JP)

(73) Assignee: NIPPON TELEGRAPH AND TELEPHONE CORPORATION, Tokyo (JP)

(21) Appl. No.: 17/916,975

(22) PCT Filed: Apr. 6, 2020
(86) PCT No.: PCT/JP2020/015539

§ 371 Date: Oct. 4, 2022

(51) Int. Cl. G06F 30/20; F24F 11/63

(52) U.S. Cl. CPC G06F 30/20; F24F 11/63; F24F 2110/10

(57) ABSTRACT

An estimation device 10 estimates a boundary condition used in a simulation of a temperature inside a target space. A boundary condition setting unit 109 of the estimation device 10 sets the boundary condition based on an actual measured value of observation data related to the target space and a parameter including a weight to the actual measured value of the observation data. Then, a simulation execution unit 110 calculates a predicted value of the observation data by executing a simulation inside the target space based on the boundary condition set. Then, an error calculation unit 112 calculates an error between the predicted value of the observation data calculated through the simulation and the actual measured value of the observation data. Then, a parameter update unit 113 estimates the parameter so as to reduce the error. Then, the parameter update unit 113 estimates the boundary condition based on the parameter estimated.

### TECHNICAL FIELD

A technique of the disclosure relates to an estimation method, a simulation method, an estimation device, and an estimation program.

### BACKGROUND ART

There is known a technique that predicts an indoor temperature based on observation data representing temperatures in the past or a crowd condition for the purpose of reducing energy consumption of an air conditioner or the like installed in, for example, an office building or a commercial facility (e.g., refer to Patent Literature 1). A technique disclosed in Patent Literature 1 controls an air conditioner based on a result of prediction of an indoor temperature. The technique disclosed in Patent Literature 1 uses a machine learning method as a method for reproducing the indoor temperature.

### CITATION LIST

### Patent Literature

Patent Literature 1: Japanese Patent Laid-Open No. 2019-060514

### SUMMARY OF THE INVENTION

### Technical Problem

In predicting a change in the indoor temperature by the machine learning method, a large amount of past data is required. On the other hand, in a building in normal operation, an air conditioner is typically controlled so as to maintain a constant indoor environment to prevent loss of comfort. Thus, in controlling an air conditioner in a building in operation, a parameter is typically unchanged.

Under such a specific environment, only biased data is acquired. Thus, it is difficult to cause a predetermined model to learn the influence of the air conditioner on the indoor temperature based on the past data. Therefore, it is considered that, in predicting a change in the indoor temperature, it is effective to use a simulator such as computational fluid dynamics (CFD), which does not depend on past data.

On the other hand, in order to precisely predict a change in the temperature inside a target space using a simulation such as CFD, it is necessary to appropriately set a boundary condition that may influence the change in the temperature. However, in a building such as an office building or a commercial facility, there is a boundary condition that cannot be directly measured.

For example, an air volume at a blowoff port of an air conditioner may differ from that of the specifications in a catalog due to the arrangement of the air conditioner or deterioration of the air conditioner over time. Thus, if no sensor is attached to the blowoff port of the air conditioner, it is difficult to measure, with time, the air volume at each blowoff port. Moreover, in a building where people come and go, there is a boundary condition that changes with time, such as outside air entering the inside of a space of the building.

Due to the reasons as described above, there is a problem in that it is difficult to appropriately estimate a boundary condition in predicting a temperature inside a target space using the existing simulation method.

The technique of the disclosure has been made in view of the above points, and an object thereof is to appropriately estimate a boundary condition used in predicting a temperature inside a target space through a simulation.

### Means for Solving the Problem

A first aspect of the present disclosure provides an estimation method for estimating a boundary condition used in a simulation of a temperature inside a target space, the estimation method including the steps executed by a computer of: setting the boundary condition based on an actual measured value of observation data related to the target space and a parameter including a weight to the actual measured value of the observation data; calculating a predicted value of the observation data by executing a simulation inside the target space based on the boundary condition set; calculating an error between the predicted value of the observation data calculated through the simulation and the actual measured value of the observation data; and estimating the parameter so as to reduce the error, and estimating the boundary condition based on the parameter estimated.

A second aspect of the present disclosure provides an estimation method for estimating a plurality of boundary conditions used in a simulation for predicting a change in a temperature inside a target space, the estimation method including the steps executed by a computer of: acquiring a plurality of types of observation data related to the target space; and estimating the plurality of boundary conditions based on the plurality of types of observation data and a parameter including a weight to the plurality of pieces of observation data. The plurality of types of observation data include the temperature inside the target space, data outside the target space influencing the temperature inside the target space, data inside the target space influencing the temperature inside the target space, and setting data of a device inside the target space influencing the temperature inside the target space.

A third aspect of the present disclosure provides an estimation device configured to estimate a boundary condition used in a simulation of a temperature inside a target space, the estimation device including: a boundary condition setting unit configured to set the boundary condition based on an actual measured value of observation data related to the target space and a parameter including a weight to the actual measured value of the observation data; a simulation execution unit configured to calculate a predicted value of the observation data by executing a simulation inside the target space based on the boundary condition set; an error calculation unit configured to calculate an error between the predicted value of the observation data calculated through the simulation and the actual measured value of the observation data; and a parameter estimation unit configured to estimate the parameter so as to reduce the error and estimate the boundary condition based on the parameter estimated.

A fourth aspect of the present disclosure provides an estimation program for estimating a boundary condition used in a simulation of a temperature inside a target space, the estimation program being for causing a computer to execute a process including: setting the boundary condition based on an actual measured value of observation data related to the target space and a parameter including a weight to the actual measured value of the observation data; calculating a predicted value of the observation data by executing a simulation inside the target space based on the boundary condition set; calculating an error between the predicted value of the observation data calculated through the simulation and the actual measured value of the observation data; and estimating the parameter so as to reduce the error, and estimating the boundary condition based on the parameter estimated.

### Effects of the Invention

According to the technique of the disclosure, it is possible to appropriately estimate a boundary condition used in predicting a temperature inside a target space through a simulation.

### BRIEF DESCRIPTION OF DRAWINGS

FIG. 1 is a block diagram illustrating a hardware configuration of an estimation device 10 according to an embodiment.

FIG. 2 is a block diagram illustrating a functional configuration of the estimation device 10 according to the embodiment.

FIG. 3 is a block diagram illustrating a hardware configuration of a simulation device 20 according to the embodiment.

FIG. 4 is a block diagram illustrating a functional configuration of the simulation device 20 according to the embodiment.

FIG. 5 is a diagram illustrating an example of an estimation process according to the embodiment.

FIG. 6 is a diagram for describing a concrete example of setting of a boundary condition.

FIG. 7 is a diagram for describing a concrete example of the setting of the boundary condition.

FIG. 8 is a diagram illustrating an example of a simulation process according to the embodiment.

FIG. 9 is a diagram illustrating a result of an example.

### DESCRIPTION OF EMBODIMENTS

Hereinbelow, an example of an embodiment of the technique of the disclosure will be described with reference to the drawings. Note that identical reference signs designate identical or equivalent elements or parts throughout the drawings. Further, the dimensional ratios in the drawings are exaggerated for convenience of explanation and may differ from the actual ratios.

In the present embodiment, a boundary condition that temporally changes or a boundary condition that cannot be directly measured is represented by a predetermined model. The model may be a function having a parameter. An estimation device 10 of the present embodiment estimates a parameter included in a boundary condition based on an actual measured value, at each time, of observation data which is data measured by a sensor installed in a target space, and estimates the boundary condition using the parameter. Here, the observation data and the boundary condition will be described. The observation data indicates sensor data itself observed by a temperature sensor or a wind sensor. The boundary condition is a constraint condition for a simulation relating to a boundary surface inside a target space (a target facility). Further, a simulation device 20 of the present embodiment performs a simulation of a temperature inside the target space using the boundary condition estimated by the estimation device 10. Accordingly, even in a case where a predetermined boundary condition is not present, a change in the temperature of the target space can be predicted if observation data related to the predetermined boundary condition can be acquired.

Hereinbelow, specific description will be made.

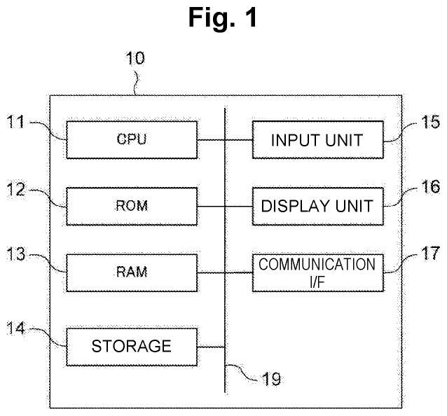

FIG. 1 is a block diagram illustrating a hardware configuration of the estimation device 10. As illustrated in FIG. 1, the estimation device 10 includes a central processing unit (CPU) 11, a read only memory (ROM) 12, a random access memory (RAM) 13, a storage 14, an input unit 15, a display unit 16, and a communication interface (I/F) 17. These elements are connected via a bus 19 communicably with each other.

The CPU 11 is a central processing unit, and executes various programs and controls each unit. That is, the CPU 11 reads a program from the ROM 12 or the storage 14 and executes the program using the RAM 13 as a work area. The CPU 11 controls each of the above-described elements and performs various arithmetic processes in accordance with the program stored in the ROM 12 or the storage 14. In the present embodiment, an estimation program for estimating a boundary condition used in a simulation is stored in the ROM 12 or the storage 14.

The ROM 12 stores various programs and various pieces of data. The RAM 13 serves as a work area and temporarily stores a program or data. The storage 14 includes a storage device such as a hard disk drive (HDD) or a solid state drive (SSD) and stores various programs including an operating system and various pieces of data.

The input unit 15 includes a pointing device, such as a mouse, and a keyboard and is used to perform various input operations.

The display 16 is, for example, a liquid crystal display and displays various pieces of information. The display unit 16 may employ a touch panel system and function as the input unit 15.

The communication interface 17 is an interface for communicating with another device such as a portable terminal or a sensor. In this communication, for example, a wired communication standard such as Ethernet (registered trademark) or FDDI or a wireless communication standard such as 4G, 5G, or Wi-Fi (registered trademark) is used.

Next, a functional configuration of the estimation device 10 will be described.

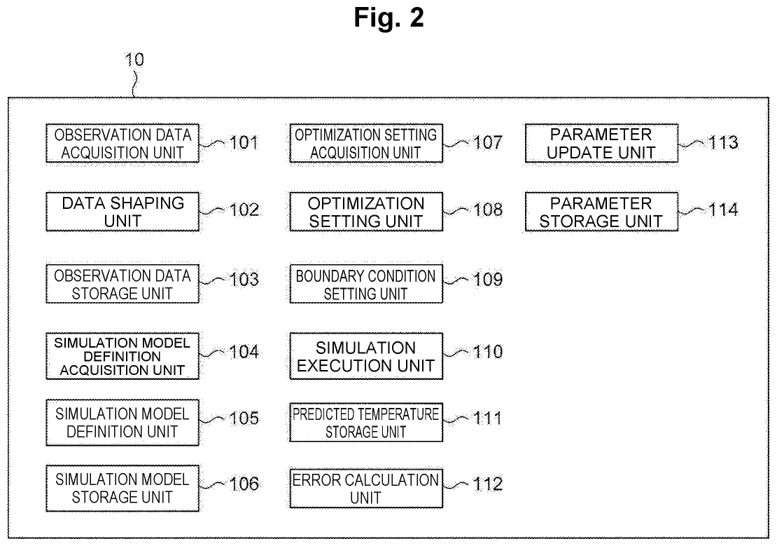

FIG. 2 is a block diagram illustrating an example of the functional configuration of the estimation device 10. The estimation device 10 estimates a boundary condition used in a simulation of a temperature inside a target space.

As illustrated in FIG. 2, the estimation device 10 includes, as the functional configuration, an observation data acquisition unit 101, a data shaping unit 102, an observation data storage unit 103, a simulation model definition acquisition unit 104, a simulation model definition unit 105, a simulation model storage unit 106, an optimization setting acquisition unit 107, an optimization setting unit 108, a boundary condition setting unit 109, a simulation execution unit 110, a predicted temperature storage unit 111, an error calculation unit 112, a parameter update unit 113, and a parameter storage unit 114. The parameter update unit 113 is an example of the parameter estimation unit of the present disclosure. Each functional unit is implemented by the CPU 11 reading the estimation program stored in the ROM 12 or the storage 14, and loading the estimation program into the RAM 13 and executing the estimation program.

The observation data acquisition unit 101 acquires an actual measured value of observation data related to the target space. The actual measured value of the observation data is, for example, data measured by an external sensor device, a device that measures data relating to a building and energy management system (BEMS), or an air-conditioning system. For example, the observation data acquisition unit 101 acquires the actual measured value of the observation data via a network.

Specifically, the observation data of the present embodiment includes temperature humidity data representing an indoor temperature or an indoor humidity inside the target space (hereinbelow, merely referred to as “room temperature data”). The observation data also includes meteorological data representing an outside air temperature, an outside air humidity, an air velocity, or weather (e.g., the amount of solar radiation) outside the target space.

The observation data also includes building and energy management system (BEMS) data representing a supply air temperature of an air conditioner, a supply air humidity of the air conditioner, a supply air volume of the air conditioner, or a valve opening degree of the air conditioner. The BEMS data also includes ON or OFF of a fan coil unit of the air conditioner, an exhaust valve opening degree of the air conditioner, or ON or OFF of an exhaust fan of the air conditioner. These pieces of data are examples of operation information representing an operating state of air conditioning.

The observation data also includes people flow data representing a people flow amount obtained by measuring movement of people passing through a certain area inside the target space or the amount of the movement. The observation data also includes another data such as operating hours of a store which is an example of the target space or an event time indicating the time when an event is held.

The observation data acquisition unit 101 may acquire, as the observation data, not only past data measured by a sensor, but also future data predicted using a method such as linear regression. Details of the observation data will be described later.

The data shaping unit 102 shapes, based on the actual measured value of the observation data acquired by the observation data acquisition unit 101, the actual measured value of the observation data into a format that can be used in the simulation of the temperature inside the target space. Specifically, the data shaping unit 102 spatially interpolates observation data in a three-dimensional space based on an installed position of each sensor such as a thermohygrometer and an actual measured value of the observation data measured by each sensor. Accordingly, observation data at each location in three dimensions inside the target space is obtained. The data shaping unit 102 performs association with a place where the actual measured value of each piece of observation data is measured. This associates each area inside the target space with the observation data, which makes it possible to determine which observation data has been obtained in which area.

The actual measured value of the observation data shaped by the data shaping unit 102 is stored in the observation data storage unit 103.

The simulation model definition acquisition unit 104 acquires definition data representing, for example, the size of the target space, the size of a calculation grid to be a calculation unit in executing the simulation of the temperature, which will be described later, an outside air inlet in the target space, or an air-conditioning blowoff port inside the target space. The definition data defies, for example, the position and the number of outside air inlets. The definition data is used in defining a simulation model and set, for example, by a user.

The simulation model definition unit 105 defines the structure of the target space, generates the calculation grid in the simulation, and sets a boundary based on the definition data acquired by the simulation model definition acquisition unit 104. Then, the simulation model definition unit 105 constructs a simulation model, which is a structure model for executing the simulation of the temperature inside the target space. Then, the simulation model definition unit 105 stores the constructed simulation model in the simulation model storage unit 106.

The simulation model constructed by the simulation model definition unit 105 is stored in the simulation model storage unit 106.

The optimization setting acquisition unit 107 acquires setting data in optimizing a parameter of the boundary condition. For example, a period or an element to be optimized or a unit or a method for calculating an error between a predicted value and the actual measured value is described in the setting data. The setting data is, for example, previously set by a user. The parameter of the boundary condition is optimized based on the setting data so as to reduce the error between the predicted value obtained through the simulation of the temperature inside the target space and the actual measured value. Details of the setting data will be described later.

The optimization setting unit 108 sets a data period used in the optimization of the parameter of the boundary condition, an element of the parameter to be optimized, and the method for calculating the error based on the setting data acquired by the optimization setting acquisition unit 107.

The boundary condition setting unit 109 sets the boundary condition used in the simulation of the temperature inside the target space based on the actual measured value of the observation data related to the target space, the actual measured value of the observation data being stored in the observation data storage unit 103, and a parameter including a weight to the actual measured value of the observation data.

Specifically, the boundary condition setting unit 109 refers to the data set by the optimization setting unit 108 according to the setting data and sets each boundary condition for the simulation model stored in the simulation model storage unit 106 based on the observation data stored in the observation data storage unit 103 and the parameter of the boundary condition stored in the parameter storage unit 114.

The boundary condition setting unit 109 sets, as an initial value of the simulation, the observation data stored in the observation data storage unit 103 (e.g., an indoor temperature, an atmospheric pressure, or a flow rate) or a fixed value.

The simulation execution unit 110 executes the simulation inside the target space based on the boundary condition set by the boundary condition setting unit 109, thereby calculating a predicted value of the observation data related to the target space.

Specifically, the simulation execution unit 110 executes the simulation model stored in the simulation model storage unit 106 in predetermined time units in accordance with the boundary condition and the initial value set by the boundary condition setting unit 109 to obtain a simulation result at each time. Then, the simulation execution unit 110 stores the simulation result at each time in the predicted temperature storage unit 111.

A predicted result of the temperature at each time, which is the simulation result calculated by the simulation execution unit 110, is stored in the predicted temperature storage unit 111.

The error calculation unit 112 calculates an error between the predicted value of the observation data stored in the predicted temperature storage unit 111 and the actual measured value of the observation data stored in the observation data storage unit 103. Specifically, the error calculation unit 112 refers to the data set by the optimization setting unit 108 according to the set data and calculates an error between the actual measured value of the observation data at each time stored in the observation data storage unit 103 and the predicted value of the observation data at each time stored in the predicted temperature storage unit 111 in a certain time slot.

The parameter update unit 113 updates the parameter of the boundary condition so as to reduce the error calculated by the error calculation unit 112. Then, the parameter update unit 113 stores the updated parameter in the parameter storage unit 114. Details of a method for updating the parameter will be described later.

The parameter updated by the parameter update unit 113 is stored in the parameter storage unit 114.

The setting of the boundary condition performed by the boundary condition setting unit 109, the calculation of the error performed by the error calculation unit 112, and the update of the parameter performed by the parameter update unit 113 are repeated, and the repetitive process is finished when a predetermined repetition condition is satisfied. As a result, an appropriate parameter for setting the boundary condition is obtained.

The parameter update unit 113 estimates the boundary condition used in the simulation based on the parameter obtained as a result of the repetitive process. Then, the parameter update unit 113 stores the estimated boundary condition in the parameter storage unit 114.

Accordingly, an appropriate boundary condition used in executing the simulation of the temperature inside the target space is obtained. The simulation device 20, which will be described later, executes the simulation of the temperature inside the target space to execute a temperature prediction process using the boundary condition or the parameter estimated by the estimation device 10.

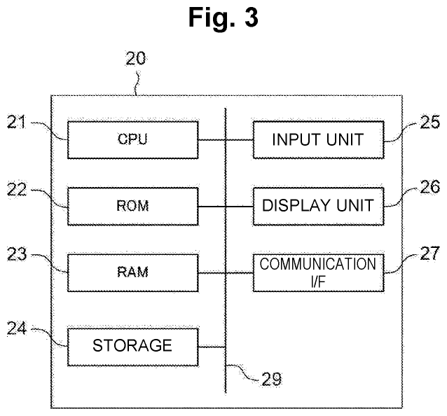

FIG. 3 is a block diagram illustrating a hardware configuration of the simulation device 20. As illustrated in FIG. 1, the simulation device 20 includes a central processing unit (CPU) 21, a read only memory (ROM) 22, a random access memory (RAM) 23, a storage 24, an input unit 25, a display unit 26, and a communication interface (I/F) 27. These elements are connected via a bus 29 communicably with each other.

The CPU 21 is a central processing unit, and executes various programs and controls each unit. That is, the CPU 21 reads a program from the ROM 22 or the storage 24 and executes the program using the RAM 23 as a work area. The CPU 21 controls each of the above-described elements and performs various arithmetic processes in accordance with the program stored in the ROM 22 or the storage 24. In the present embodiment, a simulation program for executing the simulation of the temperature inside the target space is stored in the ROM 22 or the storage 24.

The ROM 22 stores various programs and various pieces of data. The RAM 23 serves as a work area and temporarily stores a program or data. The storage 24 includes a storage device such as a hard disk drive (HDD) or a solid state drive (SSD) and stores various programs including an operating system and various pieces of data.

The input unit 25 includes a pointing device, such as a mouse, and a keyboard and is used to perform various input operations.

The display 26 is, for example, a liquid crystal display and displays various pieces of information. The display unit 26 may employ a touch panel system and function as the input unit 25.

The communication interface 27 is an interface for communicating with another device such as a portable terminal or a sensor. In this communication, for example, a wired communication standard such as Ethernet (registered trademark) or FDDI or a wireless communication standard such as 4G, 5G, or Wi-Fi (registered trademark) is used.

Next, a functional configuration of the simulation device 20 will be described.

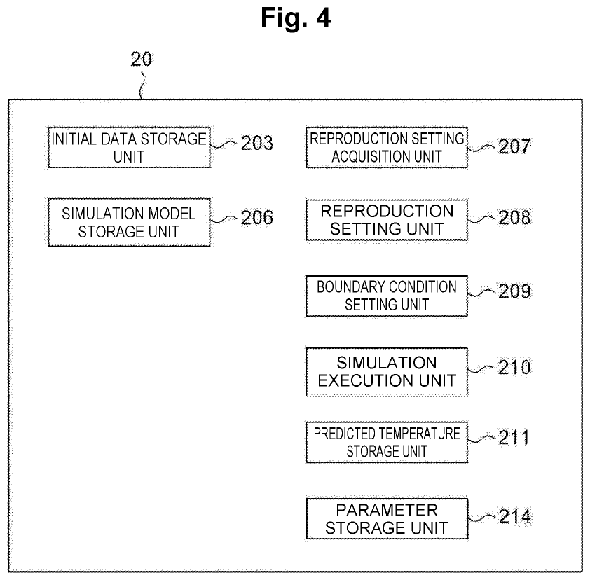

FIG. 4 is a block diagram illustrating an example of the functional configuration of the simulation device 20.

As illustrated in FIG. 4, the simulation device 20 includes, as the functional configuration, an initial data storage unit 203, a simulation model storage unit 206, a boundary condition setting unit 209, a simulation execution unit 210, a predicted temperature storage unit 211, and a parameter storage unit 214. Each functional unit is implemented by the CPU 21 reading the simulation program stored in the ROM 22 or the storage 24, and loading the simulation program into the RAM 23 and executing the simulation program.

Initial data required to execute the simulation is stored in the initial data storage unit 203. The initial data will be described later.

The simulation model is stored in the simulation model storage unit 206 as with the simulation model storage unit 106 of the estimation device 10.

A reproduction setting acquisition unit 207 acquires reproduction setting data input from a user. The reproduction setting data is set by a user and includes various conditions in performing the simulation of the temperature inside the target space. Details of the reproduction setting data will be described later.

A reproduction setting unit 208 sets the various conditions in performing the simulation of the temperature inside the target space based on the reproduction setting data acquired by the reproduction setting acquisition unit 207.

The boundary condition setting unit 209 has a function similar to the function of the boundary condition setting unit 109 of the estimation device 10.

The simulation execution unit 210 has a function similar to the function of the simulation execution unit 110 of the estimation device 10.

The predicted temperature storage unit 211 has a function similar to the function of the predicted temperature storage unit 111 of the estimation device 10.

The parameter or the boundary condition estimated by the estimation device 10 is stored in the parameter storage unit 214. In the present embodiment, an example in which the parameter estimated by the estimation device 10 is stored in the parameter storage unit 214 will be described.

Next, the action of the estimation device 10 will be described.

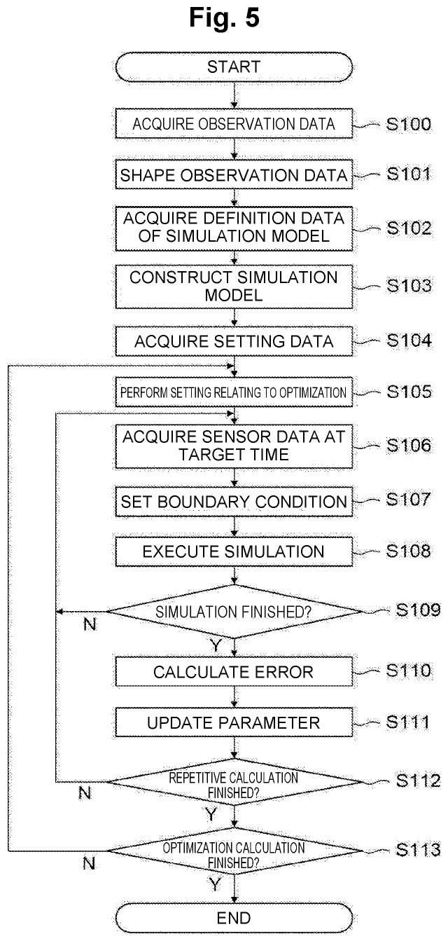

FIG. 5 is a flowchart illustrating the flow of an estimation process performed by the estimation device 10. The estimating process is performed by the CPU 11 reading the estimation program from the ROM 12 or the storage 14, and loading the estimation program into the RAM 13 and executing the estimation program.

In step S100, as the observation data acquisition unit 101, the CPU 11 acquires an actual measured value of observation data related to a target space.

In step S101, as the data shaping unit 102, the CPU 11 shapes the actual measured value of the observation data acquired in step S100. Then, as the data shaping unit 102, the CPU 11 stores the shaped actual value of the observation data in the observation data storage unit 103.

The data shaping unit 102 can use, for example, Kriging (e.g., refer to Non-patent Literature 1 below) in extending the actual measured value of the observation data at each location inside the target space to shape data in a three-dimensional space. The data shaping unit 102 can also use another method such as linear interpolation to convert the actual measured value of the observation data to data in a three-dimensional space.

Non-patent Literature 1: SHOJI, Tetsuya, and Katsuaki KOIKE. “Kriging-Estimation of Spatial data taking account of error.” Journal of the Geothermal Research Society of Japan 29. 4 (2007): 183-194.

Table 1 below shows an example of the actual measured value of the observation data shaped by the data shaping unit 102. Examples of the observation data stored in the observation data storage unit 103 include a time when data is measured, a data type representing the type of observation data, an input data number representing identification information of input data, a value of an actual measured value represented by observation data, a position where observation data is measured, and a corresponding area to which the position where observation data is measured belongs.

TABLE 1

| | | Input | | | Corre- |
|---|---|---|---|---|---|
| | | data | | | sponding |
| Time | Data type | number | Value | Position | area |
| 2019-09-23 | Outside air | 4 | 25.0 | — | — |
| 10:00:00 | temperature | | | | |
| 2019-09-23 | Indoor | 2 | 26.5 | (300.400.20) | 1 |
| 10:00:00 | temperature | | | | |
| . . . | . . . | . . . | . . . | . . . | . . . |
| . . . | . . . | . . . | . . . | . . . | . . . |

The data type is, for example, character string information for identifying the type of data such as the people flow amount or the outside air temperature. The input data number is a number obtained by counting the data type for each measurement point and identification information of data. The position represents a point where observation data is measured or corresponding coordinates obtained when observation data is three-dimensionalized by spatial interpolation. The corresponding area is information that is set based on data included in definition data acquired by the simulation model definition acquisition unit 104 and defined by a user. The corresponding area indicates an area including the position where the observation data is measured among area sections, which will be described later.

In step S102, as the simulation model definition acquisition unit 104, the CPU 11 acquires definition data of a simulation model. The definition data is input, for example, by a user.

In step S103, as the simulation model definition unit 105, the CPU 11 constructs the simulation model based on the definition data acquired in step S102. Then, as the simulation model definition unit 105, the CPU 11 stores the simulation model in the simulation model storage unit 106.

In defining the simulation model, the simulation model definition unit 105 models the target space of the simulation as a grid structure and sets the positions of boundaries such as an outside air inlet, an air-conditioning blowoff port, and an air outlet.

In this case, the simulation model definition unit 105 acquires, from the definition data, the size of the target space, the size of the calculation grid, and positional information of boundaries such as the outside air inlet, the air-conditioning blowoff port, the air outlet, and a heating element. Similarly, the simulation model definition acquisition unit 104 also acquires, from the definition data, information required for the simulation such as a time unit of calculation and a model of airflow fluctuations representing either a turbulent flow or a laminar flow.

Table 2 shows an example of the definition data acquired by the simulation model definition acquisition unit 104. The definition data shown in Table 2 is previously set by a user.

TABLE 2

| New | | | | | | | | | | |
|---|---|---|---|---|---|---|---|---|---|---|
| creation/ | | | | | | | | | | |
| existing | Exist- | | Calcu- | | | | | | | |
| model | ing | Entire | lation | Boundary surface | | | | | Calcu- | |
| creation/ | model | structure | grid | | Air | | | | lation | Turbu- |
| existing | file | size | size | Outside | conditioning | Air | Heating | | time | lent |
| model | path | (X, Y, Z) | (X, Y, Z) | air inlet | blowoff port | outlet | element | Area section | unit | flow |
| New | — | [2000, | [10, 10, | [(0, 10, 0), | [(0, 30, 30), | [(500, 0, | [(0, 10, 0), | {1: [(0, 0, 0), | 5 min | Laminar |
| | | 5000, 300] | 10] | (0, 80, 200)], | (50, 60, 30)], | 10), (505, | (0, 80, 200)], | (800, 5000, 300)], | | flow |
| | | | | [(2000, 10, | [(1000, 30, 30), | 0, 13)] | [(2000, 10, 0), | 2: [(800, 0, 0), | | |
| | | | | 0), (2000, | (1050, 60, 30)] | | (2000, 80, 200)] | (1600, 5000, 300)], | | |
| | | | | 80, 200)] | | | | 3: [(1600, 0, 0), | | |
| | | | | | | | | (2000, 5000, 300)]} | | |

The simulation model set based on the definition data may be a three-dimensional model that is previously created using an application such as 3 Dimensional computer-aided design (3DCAD). In this case, when the three-dimensional model created using the 3DCAD or the like is input, the three-dimensional model may be automatically read.

A column of “new creation/existing model” in Table 2 is used in selecting either inputting the existing three-dimensional model or creating a new set value model.

When “existing model” is set in the column of “new creation/existing model”, the simulation model definition unit 105 reads a file designated in a column of “existing model file path” in Table 2 and creates a simulation model.

On the other hand, when “new” is set in the column of “new creation/existing model”, the simulation model definition unit 105 creates a new simulation model based on each piece of data stored in a column of “entire structure size”, a column of “calculation grid size”, and a column of “boundary surface”. Specifically, the simulation model definition unit 105 creates a three-dimensional mesh structure by dividing, for each calculation grid that is set based on the calculation grid size, the entire structure of a rectangular parallelepiped whose sizes in the X-axis, Y-axis, and Z-axis directions are defined based on the entire structure size. Then, the simulation model definition unit 105 sets, for the three-dimensional mesh structure, boundaries at boundary positions defined in a column of “outside air inlet”, a column of “air-conditioning blowoff port”, a column of “air outlet”, and a column of “heating element”, which are included in a column of “boundary surface”.

In the column of “boundary surface” in Table 2, coordinates of two points are shown. The two points mean two points for representing a rectangle that is defined by two representative points and has sides parallel to any two of the X axis, the Y axis, and the Z axis. For example, “outside air inlet” shows two-point coordinates “(0, 10, 0), (0, 80, 200)”. A rectangle having a position and a size defined by the two-point coordinates represents a surface of one outside air inlet.

When a boundary surface other than the above-described boundary surfaces is present, such a boundary may be included in the column of “boundary surface” according to a building structure as the target space. A column of “area section” in Table 2 is information that is defined by a user to perform setting of conditions and evaluation of a predicted value for each of a plurality of sections obtained by dividing the whole target space. “Area section” in Table 2 includes identification information of an area and a value indicating a space corresponding to the area. For example, “area section” in Table 2 shows “1: (0, 10, 0), (0, 80, 200)”. In this information, “1” is identification information of an area, and “(0, 10, 0), (0, 80, 200)” represents a space corresponding to the area. The space corresponding to the area represents a rectangular parallelepiped that is defined by two representative points and has sides parallel to the X axis, the Y axis, and the Z axis.

“Size of entire structure” in an example of Table 2 represents a rectangular parallelepiped that is defined by two representative points and has sides parallel to the X axis, the Y axis, and the Z axis. A method for representing the space of each area is not limited to the example of Table 2, and may be a method that individually describes grid-like coordinates included in the target space or describes the space by a specific conditional expression.

A column of “calculation time unit” in Table 2 indicates a time unit for performing, in executing one simulation, the simulation. Further, the definition data may include a set value other than the above set values. For example, the definition data may include information such as a turbulent flow column indicating whether an airflow is assumed to be a turbulent flow in executing the simulation.

A boundary condition matrix shown in Table 3 below, a simulation execution parameter matrix shown in Table 4 below, and an area section matrix shown in Table 5 below are also stored in the simulation model storage unit 106 in addition to the simulation model.

TABLE 3
Boundary condition matrix

| Boundary | Boundary | | | | |
|---|---|---|---|---|---|
| condition | surface | | Setting | | Area |
| number | number | Element | object | Place | number |
| 1 | 1 | Air | Temperature | [(0, 0, 3), | 1 |
| | | conditioning | | (2, 3, 3)] | |
| 2 | 1 | Air | Air volume | [(0, 0, 3), | 1 |
| | | conditioning | | (2, 3, 3)] | |
| 3 | 2 | Outside air | Temperature | [(5, 0, 3), | 1 |
| | | | | (7, 3, 3)] | |
| . . . | . . . | . . . | . . . | . . . | . . . |

TABLE 4
Simulation execution matrix

| Execution parameter name | valu |
|---|---|
| Maximum number of executions | 144 |
| Simulation execution time unit | 10 |
| Model output step unit | 5 |
| Turbulent flow model | False |
| . . . | . . . |

TABLE 5
Area section matrix

| Area name | Target space |
|---|---|
| 1 | (0, 0, 0), (800, 5000, 300) |
| 2 | (800, 0, 0), (1600, 5000, 300) |
| 3 | (1600, 0, 0), (2000, 5000, 300) |
| . . . | . . . |

In the boundary condition matrix, information of each boundary described in “boundary surface” in the definition data acquired by the simulation model definition unit 105 is stored as a list for each boundary condition. A column of “boundary surface number” of the boundary condition matrix is identification information indicating what number boundary the boundary is among all the boundaries described in the column of “boundary surface” of the definition data in Table 2.

A column of “element” of the boundary condition matrix is a value indicating which element that influences an indoor environment each boundary condition corresponds to. For example, in the case of the boundary surface defined in the column of “outside air inlet” of the definition data in Table 2, “element” corresponding to the boundary condition matrix is “outside air”. In the case of the boundary surface defined in the column of “air-conditioning blowoff port” of the definition data in Table 2, “element” corresponding to the boundary condition matrix is “air conditioning”. In the case of the boundary surface defined in the column of “heating element” of the definition data in Table 2, “element” corresponding to the boundary condition matrix is “heat generation”.

A column of “setting object” of the boundary condition matrix indicates a setting item that is set for each boundary surface. For example, temperature and flux are set for the outside air inlet and the air-conditioning blowoff port. Pressure is set for the air outlet, and a heat amount is set for the heating element. The setting item can include two or more of items such as temperature, pressure, air velocity, air volume, thermal diffusivity, turbulent flow energy, turbulent flow energy dissipation, turbulent flow energy dissipation ratio, turbulent flow viscosity coefficient, Reynolds stress tensor, enthalpy, and internal energy.

A column of “place” of the boundary condition matrix indicates the position of each boundary set in the column of “boundary surface” of the definition data in Table 2.

A column of “area number” of the boundary condition matrix indicates which one of the areas described in the column of “area section” of the definition data in Table 2 includes the position where the boundary is present.

A parameter other than the structure information required for the simulation is stored in the execution parameter matrix. Each piece of information stored in the execution parameter matrix indicates a value included in the definition data or a value previously defined by the system. A model output step unit represents a time unit of a result output from the simulation model.

The area section matrix includes the name of each area described in the column of “area section” of the definition data of Table 2 and a value indicating a target space thereof.

In step S104, as the optimization setting acquisition unit 107, the CPU 11 acquires setting data.

In step S105, as the optimization setting unit 108, the CPU 11 performs various setting operations relating to optimization based on the setting data acquired in step S104.

Specifically, the optimization setting unit 108 sets, for example, a data period used in parameter optimization, an element of a parameter to be optimized, and a method for calculating an error, which will be described later, based on the setting data acquired by the optimization setting acquisition unit 107.

Table 6 shows an example of the setting data acquired by the optimization setting acquisition unit 107.

TABLE 6

| | | | Target date | Parameter | |
|---|---|---|---|---|---|
| Optimization | Date | Time | selection | update | Optimized |
| number | designation | designation | method | timing | Element |
| 0 | N/A | N/A | Random | 1 day | Outside air, air |
| | | | | | conditioning, |
| | | | | | heat generation, |
| | | | | | exhaust air |
| 1 | 2019 Sep. 23: | 8:00-9:00 | Ascending | All days | Air |
| | 2019 Sep. 30 | | order | | conditioning |
| . . . | . . . | . . . | . . . | . . . | . . . |

| | Error | | Error | | |
|---|---|---|---|---|---|
| Optimization | calculation | Target | calculation | Optimization | |
| number | unit | range | method | method | Stop condition |
| 0 | Whole | Z = 1.2 m | MAE | Genetic | Number of |
| | space | | | Algorithms | repetitions > 100 |
| | | | | | or Error < 0.8 |
| 1 | Area | Areas 1, 2 | Cross | Grid search | Number of |
| | | | entropy | | repetitions > 20 |
| | | | | | or Error < 0.5 |
| . . . | . . . | . . . | . . . | . . . | . . . |

“Optimization number” of the setting data in Table 6 represents the order in which the row is executed. Thus, when the optimization setting unit 108 executes step S105 for the first time, setting for a row with the optimization number “0” is executed. On the other hand, when the optimization setting unit 108 executes step S105 again after a determination process in step S113, which will be described later, setting is performed for a row having a value of the next largest optimization number after “optimization number” in the previous execution.

In a column of “date designation” of the setting data in Table 6, a period of days in which the simulation is executed is defined. In a column of “time designation” of the setting data, a time slot of a day in which the simulation is executed is defined. In a column of “target date selection method” of the setting data, a method for determining a simulation execution date in a case where a plurality of dates are included in the period designated in the column of “date designation” is defined.

A column of “optimized element” of the setting data in Table 6 can designate an element when the boundary condition to be optimized is limited. The element represents the same element as that in the column of “element” of the boundary condition matrix. A column of “error calculation unit” of the setting data represents a calculation unit used in calculating an error between the actual measured value and the predicted value. A column of “target range” of the setting data designates an area to be limited in the range designated in the error calculation unit. A column of “error calculation method” of the setting data designates a method for calculating the error. A column of “optimization method” of the setting data designates a parameter update method based on the error. A column of “stop condition” of the setting data designates a condition for finishing the optimization setting.

In step S106, as the boundary condition setting unit 109, the CPU 11 determines a target time and acquires observation data at the target time to set the boundary condition.

When the boundary condition setting unit 109 executes step S106 for the first time or when the boundary condition setting unit 109 executes step S106 for the first time in new optimization setting after the determination of step S113, which will be described later, a target “date” when the simulation is executed is first determined based on “target date selection method” of the setting data acquired by the optimization setting acquisition unit 107.

For example, when the column of “target date selection method” of the setting data is “random”, the boundary condition setting unit 109 randomly selects a date from the dates included in the period designated in the column of “date destination”. When the column of “target date selection method” of the setting data is “ascending order”, the boundary condition setting unit 109 selects a date in the order from the earliest “date” from the dates included in the period designated in the column of “date designation”.

When the column of “time designation” of the setting data is set for the date selected in this manner, the boundary condition setting unit 109 reads, from the observation data storage unit 103, observation data corresponding to the earliest time in the time designation. When the column of “time designation” is not designated, the boundary condition setting unit 109 extracts data corresponding to the earliest time on the selected date among pieces of observation data present in the observation data storage unit 103.

When the boundary condition setting unit 109 executes step S106 again in response to determination of step S109, which will be described later, or when the boundary condition setting unit 109 executes step S106 again in response to determination of step S112, which will be described later, the boundary condition setting unit 109 acquires observation data at a new target time as described below. The new target time is a time that is advanced from the previous simulation time by the simulation time unit stored in the simulation execution parameter matrix stored in the simulation model storage unit 106.

At this time, the boundary condition setting unit 109 selects the next simulation execution date based on information described in “target date selection method” of the setting data when there is no actual measured value of observation data corresponding to the determined new target time or the target time is after 24:00.

For example, when the column of “target date selection method” of the setting date is “random”, the boundary condition setting unit 109 randomly selects a date from the dates included in the period designated in the column of “date designation” of the setting data. When the column of “target date selection method” of the setting data is “ascending order”, the boundary condition setting unit 109 selects the next earliest date after the date previously selected from the dates included in the period designated in the column of “date designation”.

When the column of “time designation” of the setting data is set for the date newly selected, the boundary condition setting unit 109 reads, from the observation data storage unit 103, an actual measured value of observation data corresponding to a target time that is the earliest time in the time designation. On the other hand, when the column of “time designation” of the setting data is not designated, the boundary condition setting unit 109 reads data corresponding to a target time that is the earliest time on the selected date among pieces of observation data present in the observation data storage unit 103.

In step S107, as the boundary condition setting unit 109, the CPU 11 sets a boundary condition based on the actual measured value of the observation data acquired in step S106 and the parameter including a weight to the acquired actual measured value of the observation data.

Specifically, the boundary condition setting unit 109 reads the parameter stored in the parameter storage unit 114 and substitutes the data at the target time extracted from the observation data storage unit 103 into a function to calculate a set value of the boundary condition. The function is, for example, a linear function including a weight parameter such as Expression 1 or Expression 2 below. A calculation method in this case will be described in Concrete Example 1 and Concrete Example 2 of the boundary condition setting.

Table 7 below shows an example of the weight parameter stored in the parameter storage unit 114 in the case of Expression 1 and Expression 2.

TABLE 7

| | | Boundary condition | | |
|---|---|---|---|---|
| Parameter | Corresponding input | number of | Weight | |
| number | data item number | setting object | or bias | Value |
| 1 | 1 | 1 | weight | 0.3 |
| 2 | 1 | 2 | weight | 0.01 |
| 3 | 2 | 1 | weight | −0.2 |
| 4 | 2 | 2 | weight | 1.4 |
| 5 | — | 1 | bias | 12.1 |
| . . . | . . . | . . . | . . . | . . . |

In a column of “parameter number” in Table 7, a number as identification information of the parameter is stored. The number stored in the column of “parameter number” indicates what number parameter the parameter is among the weight parameters. A column of “corresponding input data item number” in Table 7 is a value corresponding to “input data number” of the observation data stored in the observation data storage unit 103. A column of “boundary condition number of setting object” in Table 7 indicates a value corresponding to the boundary condition number of the simulation model storage unit 106. In a column of “weight of bias” in Table 7, information for identifying whether the parameter is a weight parameter for the corresponding input data or a bias parameter in the boundary condition calculation is stored. A value of each parameter is stored in a column of “value” in Table 7.

A storage format of the parameter of the boundary condition is not limited to the format shown in Table 7. For example, the parameter may be stored in the format of a weight matrix with a row of “input data item number” and a column of “boundary condition number” and a bias vector corresponding to “boundary condition number”.

The function defining the boundary condition is not limited to a linear function such as Expression 1 or Expression 2, but may be, for example, a multidimensional function, an exponential function, a logarithmic function, a trigonometric function, or a hyperbolic function. In all of the functions, a parameter included in the function is stored in the parameter storage unit 114 in a manner similar to the above.

(Concrete Example 1 of Setting of Boundary Condition)

$$[ Math . 1 ]$$

$$Outside air inlet$$

$$( \text{Equation 1-1} )$$

$$Temperature setting {T \_o}_{i} = {w \_ ot}_{i 1} * Indoor {temperature}_{a} + {w \_ ot}_{i 2} * Outside air temperature + {b \_ ot}_{i}$$

$$( Equation 1 - 2 )$$

$$Air volume setting {U \_o}_{i} = {w \_ ou}_{i 1} * Outside air velocity + {w \_ ou}_{i 2} * People flow {amount}_{a} + {b \_ ou}_{i}$$

$$Air - conditioning blowoff port$$

$$( Equation 1 - 3 )$$

$$Temperature setting {T \_ v}_{i} = {w \_ vt}_{i 1} * Supply air temperature + {w}_{{vt}_{i 2}} * Indoor {temperature}_{a} + {b \_ vt}_{i}$$

$$( Equation 1 - 4 )$$

$$Air volume setting {U \_ v}_{i} = {w \_ vu}_{i 1} * Supply air volume + {w}_{{vu}_{i 2}} * Value opening {degree}_{a} + {b \_ vu}_{i}$$

$$Air outlet$$

$$( Equation 1 - 5 )$$

$$Exhuast air volume {U \_ e}_{i} = {w \_ eu}_{i1} * Exhaust valve opening {degree}_{a} + {b \_ eu}_{i}$$

$$Internal heat generation$$

$$( Equation 1 - 6 )$$

$$Internal heat generation {W \_ in}_{i} = {w \_ tw}_{i 1} * People flow {amount}_{a} + {w}_{{w}_{i 2}} * Store open flag + {b \_ iw}_{i}$$

$$Wall surface$$

$$( Equation 1 - 7 )$$

$$Temperature setting {T \_ w}_{i} = {w \_ wt}_{i 1} * Indoor {temperature}_{a} + {w \_ wt}_{i 2} * Outside air {temperature}_{a} + {b \_ wt}_{i}$$

$$( Equation 1 - 8 )$$

$$Heat generation amount {W \_ w}_{i} = {w \_ ww}_{i 1} * Solar radiation amount + {w \_ ww}_{2} * Outside air temperature + {b \_ ww}_{i}$$

Hereinbelow, (Expression 1-1) to (Expression 1-8) listed above will be described. In the expressions, “i” corresponds to “boundary condition number”. Each of the indoor temperature, the outside air temperature, the outside air velocity, the solar radiation amount, the people flow amount, the supply air temperature, the supply air volume, the valve opening degree, the exhaust valve opening degree, and the store open flag indicates a numerical value present in the value column for data having the corresponding data type in the column of “data type” among actual measured values of the observation data stored in the observation data storage unit 103, the actual measured values being previously extracted at one time point in step S106.

In the expressions, “a” denotes the area number of data whose “boundary condition number” is “i”, the data being stored in the simulation model storage unit 106. For example, “indoor temperature a” indicates a numerical value in the value column of data whose corresponding area corresponds to “a” among pieces of data whose “data type column” is “indoor temperature” at the time stored in the observation data storage unit 103. When there are a plurality of pieces of data whose “corresponding area” corresponds to “a”, the mean thereof can be treated as a target numerical value.

“T_oᵢ” denotes a set value of a temperature at a boundary corresponding to the outside air inlet. “U_oᵢ” denotes a set value of an air volume at the outside air inlet. “T_vᵢ” denotes a set value of a temperature at the air-conditioning blowoff port. “U_vᵢ” denotes a set value of an air volume corresponding to the air-conditioning blowoff port. “U_eᵢ” denotes a set value of an air volume corresponding to the air outlet. “W_inᵢ” denotes a set value of a heat generation amount at a boundary corresponding to the internal heat generation. “T_wᵢ” denotes a set value of a temperature at a boundary corresponding to the wall surface. “W_wᵢ” denotes a set value of a heat generation amount at the boundary corresponding to the wall surface. “w_otᵢ” denotes a weight to input data for temperature setting at the boundary “i” of each outside air inlet. “b_otᵢ” denotes a bias specific to the boundary “i”, the bias being independent of input data, for the temperature setting at the outside air inlet. Similarly, “w_ouᵢ” denotes a weight to input data such as the air velocity of meteorological data or the people flow amount for air volume setting at the outside air inlet. “b_ouᵢ” denotes a bias specific to the boundary “i” for the air volume setting at the outside air inlet. “w_vtᵢ” denotes a weight to input data such as the supply air temperature of air conditioning or the corresponding area temperature for temperature setting at the air-conditioning blowoff port. “b_vtᵢ” denotes a bias specific to the boundary “i” for the temperature setting at the air-conditioning blowoff port. “w_vuᵢ” denotes a weight to input data for air volume setting at the air-conditioning blowoff port. “b_vuᵢ” denotes a bias specific to the boundary “i” for the air volume setting at the air-conditioning blowoff port. “w_euᵢ” denotes a weight to input data for air volume setting at the air outlet. “b_euᵢ” denotes a bias specific to the boundary “i” for the air volume setting at the air outlet. “w_iwᵢ” denotes a weight to input data for a set value of the heat generation amount of the internal heat generation. “b_iwᵢ” denotes a bias specific to the boundary “i” for the set value of the heat generation amount of the internal heat generation. “w_wtᵢ” denotes a weight to input data for temperature setting at the wall surface. “b_wtᵢ” denotes a bias specific to the boundary “i” for the temperature setting at the wall surface. “w_wwᵢ” denotes a weight to input data for a set value of the heat generation amount at the wall surface. “b_iwᵢ” denotes a bias specific to the boundary “i” for the set value of the heat generation amount at the wall surface.

When no information of the valve opening degree for each area is present, for example, an inverter frequency or a fan driving time of a fan coil unit can be used instead of the valve opening degree.

The store open flag is a value indicating, when a store is present in a predetermined target space, whether the time corresponds to operating hours of the store. When power consumption inside the store or another detailed data is present, such data can be used instead. When no store is present, the store open flag is not included in Expression 1-6.

A floor surface temperature may further be used as the boundary condition. In this case, when a boundary condition of the floor surface temperature is set, the indoor temperature can be used as observation data.

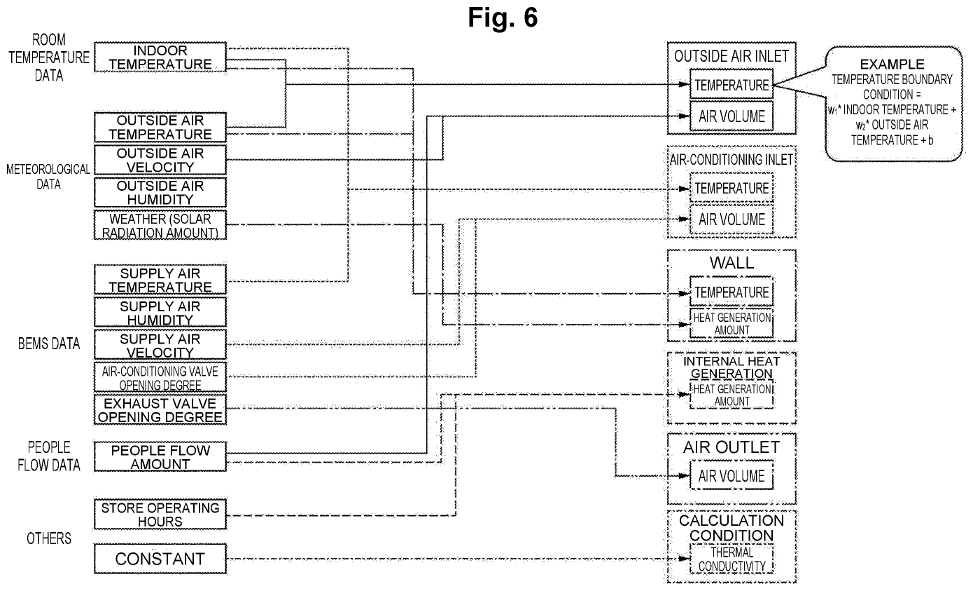

FIG. 6 is a schematic diagram of Concrete Example 1 of the setting of the boundary condition. For example, as illustrated in FIG. 6, the boundary condition relating to the temperature setting at the outside air inlet is represented by the total sum of the weighted sum of the indoor temperature and the outside air temperature and the bias. The other boundary conditions are represented by relationships as illustrated in FIG. 6.

(Concrete Example 2 of Setting of Boundary Condition)

When the relation between the boundary condition and data cannot be previously defined as shown in Expression 1 or when the influence of data other than data that seems to have a relation with the boundary condition is also taken into consideration, the relation between the data and the boundary condition can be described as in Expression 2 below. In Expression 2, “i” denotes the boundary condition number, and “j” denotes the input data number.

$$\begin{matrix}[ Math . 2 ] & \\ {y}_{i} = {\sum }_{j}^{J} {w}_{ij} {x}_{j} + {b}_{i} & ( Expression 2 )\end{matrix}$$

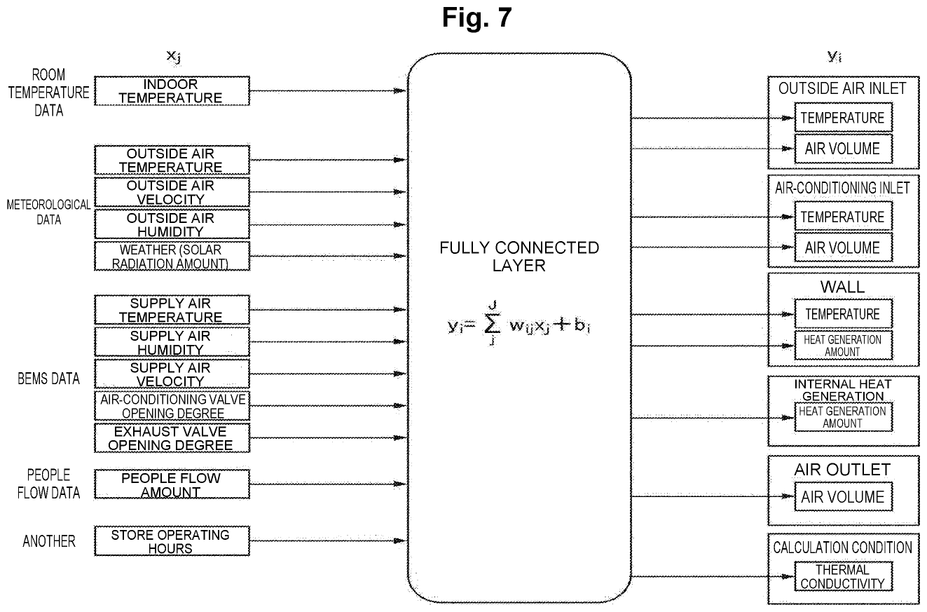

In Expression 2, “yᵢ” denotes the i-th boundary condition, “xⱼ” denotes a value of the j-th observation data, and “J” denotes the total number of pieces of observation data used in setting of the boundary condition. FIG. 7 is a schematic diagram of Concrete Example 2 of the setting of the boundary condition. For example, as illustrated in FIG. 7, a neural network model may be used to define the relation between the boundary condition and the observation data.

The boundary condition setting unit 109 sets the boundary condition calculated by the above-described means for the simulation model stored in the simulation model storage unit 106. Upon completion of the setting of the boundary condition, the boundary condition setting unit 109 outputs, to the simulation model execution unit 110, a command for simulation execution and the simulation model with the boundary condition set.

In step S108, as the simulation execution unit 110, the CPU 11 executes the simulation of the temperature inside the target space based on the boundary condition set in step S107.

Specifically, when the simulation execution unit 110 receives the simulation model and the simulation execution command from the boundary condition setting unit 109, the simulation execution unit 110 executes the simulation of the temperature inside the target space.

Then, the simulation execution unit 110 stores, in the predicted temperature storage unit 111, a predicted temperature obtained by executing the simulation. The simulation execution unit 110 may use, for example, a numerical value simulation by CFD or a model obtained from the boundary condition by association with the temperature or a temperature change inside the target space.

In step S109, as the simulation execution unit 110, the CPU 11 determines whether to finish the simulation by determining whether the current time advanced through the repetition of steps S106 to S108 is past the period designated in the parameter update timing of the setting data acquired by the optimization setting acquisition unit 107. When the current time advanced through the repetition of steps S106 to S108 is past the period designated in the parameter update timing, the process proceeds to step S110. On the other hand, when the current time advanced through the repetition of steps S106 to S108 is not past the period designated in the parameter update timing, the process returns to step S106.

In step S110, as the error calculation unit 112, the CPU 11 calculates an error between the predicted value of the observation data calculated through the simulation in step S108 and the actual measured value of the observation data stored in the observation data storage unit 103.

Specifically, the error calculation unit 112 refers to the column of “error calculation unit”, the column of “target range”, and the column of “error calculation method” set in the setting data acquired by the optimization setting acquisition unit 107 and calculates the error between the simulation result stored in the predicted temperature storage unit 111 and the actual measured value of the observation data stored in the observation data storage unit 103.

In calculating the error, the error calculation unit 112 refers to a set value in the column of “error calculation method” of the setting data acquired in step S104 and calculates the error by the error calculation method. As the set value, an error calculation method such as “MSE” (Mean Square Error; Expression 3-1), “RMSE” (Root Mean Square; Expression 3-2), “MAE” (Mean Absolute Error; Expression 3-3), “EVS” (Explained Variance Score; Expression 3-4), “correlation coefficient” (Expression 3-5), “covariance coefficient” (Expression 3-6), “cosine similarity” (Expression 3-7), or “cross entropy” (Expression 3-8) may be used. On the other hand, an index for calculating the error is not limited to these indexes. The error may be appropriately designed depending on the purpose.

$$\begin{matrix}[ Math . 3 ] & \\ MSE = \frac{1}{n} {\sum }_{i = 1}^{n} {( {pred}_{i} - {obs}_{i} )}^{2} & ( Expression 3 - 1 )\end{matrix}$$

$$RMSE = \sqrt{\frac{1}{n} {\sum }_{i = 1}^{n} {( {pred}_{i} - {obs}_{i} )}^{2}} \qquad ( Expression 3 - 2 )$$

$$MAE = \frac{1}{n} {\sum }_{i = 1}^{n} \vert {pred}_{i} - {obs}_{i} \vert \qquad ( Expression 3 - 3 )$$

$$EVS = 1 - \frac{Var ( pred - obs )}{Var ( obs )} \qquad ( Expression 3 - 4 )$$

$$r = \frac{\frac{1}{n} {\sum }_{i = 1}^{n} ( {pred}_{i} - \overline{pred} ) ( {obs}_{i} - \overline{obs} )}{\begin{matrix}\sqrt{\frac{1}{n} {\sum }_{i = 1}^{n} {( {pred}_{i} - \overline{pred} )}^{2}} \\ \sqrt{\frac{1}{n} {\sum }_{i = 1}^{n} {( {obs}_{i} - \overline{obs} )}^{2}}\end{matrix}} \qquad ( Expression 3 - 6 )$$

$$cov = \frac{1}{n} {\sum }_{i = 1}^{n} ( {pred}_{i} - \overline{pred} ) ( {obs}_{i} - \overline{obs} ) \qquad ( Expression 3 - 6 )$$

$$cosine similarity = \frac{{\sum }_{i = 1}^{n} {pred}_{i} {obs}_{i}}{\sqrt{{\sum }_{i = 1}^{n} {pred}_{i}^{2}} \sqrt{{\sum }_{i = 1}^{n} {obs}_{i}^{2}}} \qquad ( Expression 3 - 7 )$$

$$cross entropy = - {\sum }_{i = 1}^{n} {obs}_{i} log ( {pred}_{i} ) \qquad ( Expression 3 - 8 )$$

The error evaluation method described above can be used for a difference between the predicted value and the actual measured value at the previous time. In Expression 3, “obsᵢ” is a value of the actual measured value at each point of time, and “predᵢ” is the predicted value obtained through the simulation.

For example, “whole space”, “area” or “specific point” can be set as the set value in the column of “error calculation unit” designated in the setting data.

When “whole space” is designated in the setting data, the error is calculated for predicted values of all grid points of a three-dimensional space simulated for the time, the predicted values being stored in the predicted temperature storage unit 111, and interpolated values of all grid points at the time spatially interpolated in three dimensions, the interpolated values being stored in the observation data storage unit 103.

When “area” is designated in the setting data, the error is separately calculated for each space corresponding to each area.

When “specific point” is designated in the setting data, the error is calculated for each designated point.

In the column of “target range” designated in the setting data, a constraint to the target space can be described. A coordinate constraint expression or a target area can be described. For example, when “Y=120” is input, only a plane corresponding to “Y=120” is subjected to error calculation. When “area=1 or 2” is input, only a space having “1” or “2” in the column of “corresponding area” stored in the observation data storage unit 103 is subjected to error calculation.

In step S111, as the parameter update unit 113, the CPU 11 updates the parameter of the boundary condition so as to reduce the error calculated in step S110.

As the parameter update method performed by the parameter update unit 113, the method set in the column of the optimization method in the setting data acquired in step S104 is used. In the parameter update, various optimization methods such as a constrained nonlinear optimization method (Non-patent Literature 2), genetic algorithms (Non-patent Literature 3), simulated annealing (Non-patent Literature 4), and grid search (Non-patent Literature 5) are used. The parameter update object is an element input in the column of “optimized element” in the setting data. The parameter update is not performed on an element that is not included in the parameter update object.
Non-patent Literature 2: Byrd, R. H., J. C. Gilbert, and J. Nocedal. “A Trust Region Method Based on Interior Point Techniques for Nonlinear Programming.” Mathematical Programming, Vol 89, No. 1, 2000, pp. 149-185.
Non-patent Literature 3: Hiroaki KITANO, “Genetic Algorithms”, Journal of Japanese Society for Artificial Intelligence 7. 1 (1992): 26-37.
Non-patent Literature 4: Kirkpatrick, Scott, C. Daniel Gelatt, and Mario P. Vecchi. “Optimization by simulated annealing.” science 220.4598 (1983): 671-680.
Non-patent Literature 5: https://scikit-learn.org/stable/modules/generated/sklearn.model_selection.GridSearchCV.html

In step S112, as the parameter update unit 113, the CPU 11 determines whether to finish the repetitive calculation.

Specifically, the parameter update unit 113 determines whether the error calculated in step S110 or the number of repetitions satisfies a condition that is set in the stop condition column of the corresponding row in the setting data acquired by the optimization setting acquisition unit 107. When it is determined that the stop condition is satisfied, the process proceeds to step S113. On the other hand, when it is determined that the stop condition is not satisfied, and the calculation is continued, the process shifts to step S106, and processes of step S106 and thereafter are performed again.

In step S113, as the parameter update unit 113, the CPU 11 determines whether to finish the optimization calculation.

Specifically, the parameter update unit 113 refers to the setting data and determines whether the current process is a final process. When the current process is not the final process, the process of S105 is executed for the optimization process corresponding to the next optimization number. When it is determined that the current process is the final process, the process is finished.

Next, the action of the simulation device 20 will be described.

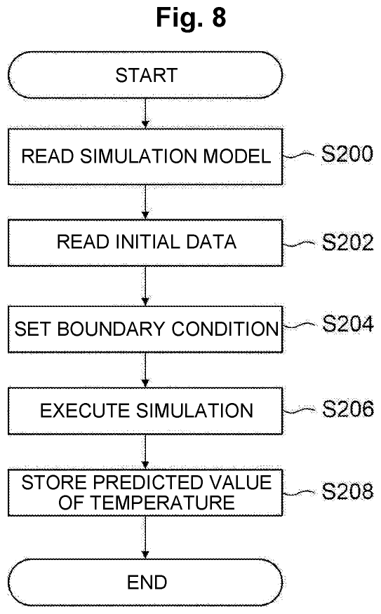

FIG. 8 is a flowchart illustrating the flow of a simulation process performed by the simulation device 20. The simulation process is performed by the CPU 21 reading the simulation program from the ROM 22 or the storage 24, and loading the simulation program into the RAM 23 and the executing the simulation program.

When the estimation process of FIG. 5 has been finished and the optimum parameter has already been obtained, prediction of the temperature inside the target space can be performed by performing the simulation process illustrated in FIG. 8.

When parameter estimation is performed in a building having a similar structure, a parameter previously estimated in the similar facility can be used. Further, when prediction is performed without any consideration of accuracy, the temperature may be predicted using the initial value of the parameter or data described by a user in the same format as the data format stored in the parameter storage unit 214.

In step S200, as the boundary condition setting unit 209, the CPU 21 reads a simulation model stored in the simulation model storage unit 206.

In step S201, as the reproduction setting unit 208, the CPU 21 refers to reproduction setting data acquired by the reproduction setting acquisition unit 207 and sets various conditions in performing the simulation of the temperature inside the target space.

The reproduction setting data represents various conditions in performing the simulation of the temperature inside the target space and includes “date designation” and “time designation” of the setting data in Table 6.

In step S202, as the boundary condition setting unit 209, the CPU 21 acquires initial data stored in the initial data storage unit 203, the initial data being related to the target space and being for executing the simulation of the temperature inside the target space.

The initial data includes initial values of, for example, indoor temperature data, meteorological data, BEMS data, and people flow data inside the target space for which the simulation is to be executed. The boundary condition is set based on the initial data in the process described below.

In step S204, as the boundary condition setting unit 209, the CPU 21 sets the boundary condition used in the simulation of the temperature inside the target space based on the initial data read in step S202 and the parameter stored in the parameter storage unit 214.

In step S206, as the simulation execution unit 210, the CPU 21 predicts the temperature in the target space by executing the simulation inside the target space based on the boundary condition set in step S204.

In step S208, as the simulation execution unit 110, the CPU 21 acquires a predicted value of the temperature inside the target space from the prediction result of the temperature calculated in step S206 and stores the predicted value of the temperature in the predicted temperature storage unit 111.

As described above, the estimation device 10 of the present embodiment estimates a boundary condition used in a simulation of a temperature inside a target space. Specifically, the estimation device 10 sets the boundary condition based on an actual measured value of observation data related to the target space and a parameter including a weight to the actual measured value of the observation data. Then, the estimation device 10 calculates a predicted value of the observation data by executing a simulation inside the target space based on the set boundary condition. Then, the estimation device 10 calculates an error between the predicted value of the observation data calculated through the simulation and the actual measured value of the observation data and estimates the parameter so as to reduce the error. Then, the estimation device 10 estimates the boundary condition based on the estimated parameter. Accordingly, it is possible to appropriately estimate the boundary condition used in predicting the temperature inside the target space through the simulation.

Further, the estimation device 10 of the present embodiment estimates a plurality of boundary conditions used in a simulation for predicting a change in a temperature inside a target space. The estimation device 10 acquires a plurality of types of observation data related to the target space, and estimates the plurality of boundary conditions based on the plurality of types of observation data and a parameter including a weight to the plurality of pieces of observation data. The plurality of types of observation data include the temperature inside the target space, data outside the target space influencing the temperature inside the target space, data inside the target space influencing the temperature inside the target space, and setting data of a device inside the target space influencing the temperature inside the target space.

The simulation device 20 of the present embodiment acquires initial data related to a target space and being for executing a simulation of a temperature inside the target space. Then, the simulation device 20 sets a boundary condition used in the simulation of the temperature inside the target space based on the acquired initial data and the parameter obtained by the estimation device 10, and predicts the temperature inside the target space by executing the simulation inside the target space based on the set boundary condition. Accordingly, it is possible to predict the temperature inside the target space using the boundary condition appropriately obtained by the estimation device 10.

### Example

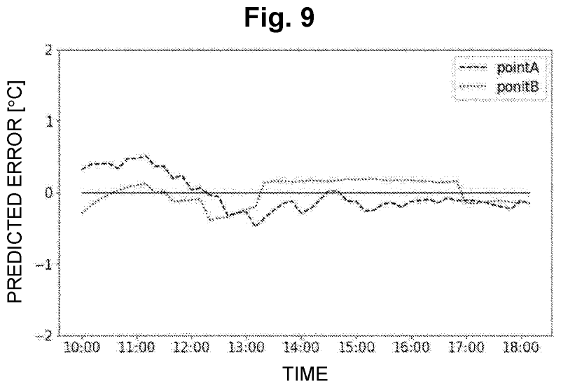

Next, an example of the above-described embodiment will be described. FIG. 9 illustrates an error between a predicted value of a temperature inside a target space predicted using the simulation device 20 of the present embodiment and an actual measured value of the temperature actually measured by a sensor. Note that “point A” and “point B” represent certain points inside the target space.

As illustrated in FIG. 9, when the estimation device 10 of the present embodiment accurately calculates the parameter for setting the boundary condition, it is possible to obtain the predicted value of the temperature inside the target space with a mean absolute error of 1° C. or less.

### Modification

Next, modifications of the present embodiment will be described.

<Modification 1>

(Estimation of Parameter Relating to Individual Optimized Elements)

In predicting a temperature inside a target space through a simulation of the temperature, elements inside the target space may influence each other. For example, the inflow of outside air into the target space and air conditioning inside the target space may influence each other, and the inflow of outside air may cancel the effect of the air conditioning. Thus, in predicting the temperature inside the target space, it is necessary to appropriately take into consideration elements that influence each other.

Thus, in Modification 1, a time slot when or a space where each specific element has a large influence is identified, and the degrees of the influences of the specific elements are individually estimated. An effective method for the estimation on each of the elements is as described below.

(Estimation Example of Element of Air Conditioning)

An element of air conditioning inside the target space largely influences the temperature at the timing when the air conditioning is started and the timing when the air conditioning is stopped. Thus, in executing the simulation, the optimization setting unit 108 sets “time designation” in the setting data to one hour before and after the air conditioning is turned ON/OFF. The optimization setting unit 108 sets “optimized element” in the setting data to “air conditioning”. The optimization setting unit 108 sets “error calculation unit” in the setting data to “whole”. The optimization setting unit 108 sets “error calculation method” in the setting data to “time difference”. Accordingly, the influence of the element of the air conditioning is taken into consideration, and the predicted value of the temperature can be appropriately estimated.

(Estimation Example of Element of Outside Air)

The vicinity of an entrance of a building, which is an example of the target space, is largely influenced by the outside air temperature, whereas the inside of the building is less influenced by the outside air temperature. Thus, the optimization setting unit 108 sets “optimized element” in the setting data to “outside air”, sets “error calculation unit” to each area section, and sets “target range” to an area around the entrance. A method that extracts a period with large differences in the outside air temperature during the daytime may be used as a method for designating a period. In this case, dates with large variations in the daily maximum temperature in the same season are selected from the observation data storage unit 103. The method for designating a period may be a designation method merely using a date with large changes in the outside air temperature during the daytime. In this case, a date with large variations in the temperature during the daytime is selected from the observation data storage unit 103. Accordingly, the influence of the outside air can be appropriately taken into consideration.

(Estimation Example of Element of Internal Heat Generation Amount)

It is expected that the internal heat generation varies from place to place even inside the same building. An average influence of the internal heat generation in the whole space inside the building can be taken into consideration. However, in order to accurately predict the temperature, it is necessary to reproduce heat generation specific to each place inside the building. In this case, the optimization setting unit 108 sets “optimized element” in the setting data to “heat generation”, and sets “error calculation unit” to each area section. Accordingly, it is possible to predict the temperature inside the building taking into consideration the influence of heat generation in each area inside the building.

(Estimation Example of Stationary Component)

In executing the simulation of the temperature inside the target space, for a factor with little variation with time, the nighttime when an external influence is assumed to be small is used as a target time. Accordingly, the temperature can be predicted with higher accuracy. For example, not many people come and go during the nighttime. Thus, the temperature can be accurately predicted without taking people flow into consideration. Thus, in predicting the temperature during the nighttime, the optimization setting unit 108 can set “optimized element” in the setting data to “exhaust air” and “heat generation”, and set “error calculation unit” in the setting data to “whole” to perform estimation.

<Modification 2>

(Period Selection for Simplification of Calculation)

When the boundary condition is estimated by performing the simulation for the entire period in which observation data is measured, an enormous amount of calculation time is required. However, the similarity of temperature fluctuations during the daytime within the same season is high. Thus, for example, in the parameter estimation of the boundary condition, the boundary condition is estimated using observation data on a specific date belonging to a certain season. Then, the simulation of the temperature for a date similar to the specific date is executed based on the boundary condition estimated using the observation data on the specific date. Accordingly, the calculation amount can be reduced.

In this case, the optimization setting unit 108 sets a specific date. Then, the parameter update unit 113 estimates the boundary condition using observation data measured on the specific date. The specific date may be (1) the most average date among dates on which the observation data stored in the observation data storage unit 103 is measured. Alternatively, (2) the specific date can also be set in response to a user's request.

In the case of (1), when the optimization setting unit 108 sets “target date selection method” in the setting data to “average date”, observation data in the observation data storage unit 103 corresponding to the date corresponding to “date designation” in the setting data is acquired. Then, the mean of the outside air temperatures at respective times on the date corresponding to “date designation” is calculated. Next, the similarity between time-series data of the mean of the outside air temperatures at respective times on the date corresponding to “date designation” and time-sires data of the outside air temperature on another date is calculated. As a method for calculating the similarity, for example, “correlation coefficient”, “covariance coefficient”, “cosine similarity”, or “Kullback-Leibler (KL) divergence” can be used. Among a plurality of similarities calculated, another date having the highest similarity can be selected as “target date”. These processes can be executed instead of the process of (1) in step S106 described above. Accordingly, it is possible to estimate a boundary condition using observation data of another date similar to the target date for which the temperature inside the target space is to be predicted and predict the temperature on the target date using the estimated boundary condition.

In the case of (2), when a user performs “date designation”, the temperature on a date corresponding to a specific date can be predicted by inputting a single date without setting a period including a plurality of dates.

Note that, in the above embodiment, various processors other than the CPU may execute each process executed by the CPU reading the software (program). Examples of the processor in this case include a programmable logic device (PLD) whose circuit configuration can be changed after manufacture such as a field-programmable gate array (FPGA) and a dedicated electric circuit which is a processor having a circuit configuration designed to be dedicated for execution of a specific process such as an application specific integrated circuit (ASIC). Further, each process may be executed by one of the various processors, or may be executed by a combination of two or more of the same type or different types of processors (e.g., a combination of a plurality of FPGAs or a combination of a CPU and an FPGA). Further, the hardware structure of the various processors is, more specifically, an electric circuit in which circuit elements such as semiconductor elements are combined.

Although, in the above embodiment, an aspect in which each program is previously stored (installed) in the storage 14 or the storage 24 has been described, the present invention is not limited thereto. The program may be provided in the form of being stored on a non-transitory storage medium such as a compact disk read only memory (CD-ROM), a digital versatile disk read only memory (DVD-ROM), or a universal serial bus (USB) memory. Further, the program may be downloaded from an external device via a network.

For the embodiment described above, the following supplements are further disclosed.

(Supplementary Item 1)

An estimation device comprising:

a memory; and

at least one processor connected to the memory, wherein

the processor is configured to

estimate a boundary condition used in a simulation of a temperature inside a target space,

set the boundary condition based on an actual measured value of observation data related to the target space and a parameter including a weight to the actual measured value of the observation data,

calculate a predicted value of the observation data by executing a simulation inside the target space based on the boundary condition set,

calculate an error between the predicted value of the observation data calculated through the simulation and the actual measured value of the observation data, and

estimate the parameter so as to reduce the error, and estimate the boundary condition based on the parameter estimated.

(Supplementary Item 2)

A non-transitory storage medium storing a program executable by a computer to execute an estimation process,

the estimation process being configured to estimate a boundary condition used in a simulation of a temperature inside a target space and comprising:

setting the boundary condition based on an actual measured value of observation data related to the target space and a parameter including a weight to the actual measured value of the observation data;

calculating a predicted value of the observation data by executing a simulation inside the target space based on the boundary condition set;

calculating an error between the predicted value of the observation data calculated through the simulation and the actual measured value of the observation data; and

estimating the parameter so as to reduce the error, and estimating the boundary condition based on the parameter estimated.

(Supplementary Item 3)

An estimation device comprising:

a memory; and

at least one processor connected to the memory, wherein

the processor is configured to

estimate a plurality of boundary conditions used in a simulation for predicting a change in a temperature inside a target space,

acquire a plurality of types of observation data related to the target space, and

estimate the plurality of boundary conditions based on the plurality of types of observation data and a parameter including a weight to the plurality of pieces of observation data, wherein

the plurality of types of observation data include the temperature inside the target space, data outside the target space influencing the temperature inside the target space, data inside the target space influencing the temperature inside the target space, and setting data of a device inside the target space influencing the temperature inside the target space.

(Supplementary Item 4)

A non-transitory storage medium storing a program executable by a computer to execute an estimation process,

the estimation process being configured to estimate a plurality of boundary conditions used in a simulation for predicting a change in a temperature inside a target space and comprising:

acquiring a plurality of types of observation data related to the target space, and

estimating the plurality of boundary conditions based on the plurality of types of observation data and a parameter including a weight to the plurality of pieces of observation data, wherein

the plurality of types of observation data include the temperature inside the target space, data outside the target space influencing the temperature inside the target space, data inside the target space influencing the temperature inside the target space, and setting data of a device inside the target space influencing the temperature inside the target space.

### REFERENCE SIGNS LIST

1 Observation data acquisition unit
102 Data shaping unit
103 Observation data storage unit
104 Simulation model definition acquisition unit
105 Simulation model definition unit
106 Simulation model storage unit
107 Optimization setting acquisition unit
108 Optimization setting unit
109 Boundary condition setting unit
110 Simulation execution unit
111 Predicted temperature storage unit
112 Error calculation unit
113 Parameter update unit
114 Parameter storage unit
201 Observation data acquisition unit
202 Data shaping unit
203 Observation data storage unit
203 Initial data storage unit
206 Simulation model storage unit
209 Boundary condition setting unit
210 Simulation execution unit
211 Predicted temperature storage unit
214 Parameter storage unit

1. An estimation method for estimating a boundary condition used in a simulation of a temperature inside a target space, the estimation method in which a processor executes processing, the processing comprising:
setting the boundary condition based on an actual measured value of observation data related to the target space and a parameter including a weight to the actual measured value of the observation data;
calculating a predicted value of the observation data by executing a simulation inside the target space based on the boundary condition set;
calculating an error between the predicted value of the observation data calculated through the simulation and the actual measured value of the observation data; and
estimating the parameter so as to reduce the error, and estimating the boundary condition based on the parameter estimated.

2. The estimation method according to claim 1, wherein the observation data includes:
the temperature inside the target space;
an outside air temperature in an area within a predetermined range outside the target space;
operating information indicating an operating state of air conditioning inside the target space; and
people flow data indicating the number of people present inside the target space.

3. The estimation method according to claim 1, wherein the setting of the boundary condition, the calculation of the error, and the update of the parameter are repeated in estimating the boundary condition.

4. A simulation method in which a processor executes processing, the processing comprising:
acquiring initial data related to a target space and being for executing a simulation of a temperature inside the target space;
setting a boundary condition used in the simulation of the temperature inside the target space based on the initial data acquired and the parameter obtained by the estimation method according to claim 1; and
predicting the temperature in the target space by executing the simulation inside the target space based on the boundary condition set.

5. The simulation method according to claim 4, wherein the initial data includes:
the temperature inside the target space;
an outside air temperature in an area within a predetermined range outside the target space;
operating information indicating an operating state of air conditioning inside the target space; and
people flow data indicating the number of people present inside the target space.

6. (canceled)

7. An estimation device configured to estimate a boundary condition used in a simulation of a temperature inside a target space, the estimation device comprising: a memory; and at least one processor coupled to the memory, the at least one processor being configured to:
set the boundary condition based on an actual measured value of observation data related to the target space and a parameter including a weight to the actual measured value of the observation data;
calculate a predicted value of the observation data by executing a simulation inside the target space based on the boundary condition set;
calculate an error between the predicted value of the observation data calculated through the simulation and the actual measured value of the observation data; and
estimate the parameter so as to reduce the error and estimate the boundary condition based on the parameter estimated.

8. A non-transitory recording medium storing an estimation program for estimating a boundary condition used in a simulation of a temperature inside a target space, the estimation program being for causing a computer to execute a process comprising:
setting the boundary condition based on an actual measured value of observation data related to the target space and a parameter including a weight to the actual measured value of the observation data;
calculating a predicted value of the observation data by executing a simulation inside the target space based on the boundary condition set;
calculating an error between the predicted value of the observation data calculated through the simulation and the actual measured value of the observation data; and
estimating the parameter so as to reduce the error, and estimating the boundary condition based on the parameter estimated.
